(19) United States
(12) Patent Application Publication
(10) Pub. No.: US 2026/0236628 A1
(43) Pub. Date: Aug. 13, 2026

(54) ESTIMATION AND VISUALIZATION PIPELINE

(71) Applicant: Paradigm, LLC, Middleton, WI (US)

(72) Inventors: Jean-Daniel Daigle, Masouche (CA); Kelly Porter, Middleton, WI (US); Mohammad Zagnoon, Middleton, WI (US); Kari Tamminga, Middleton, WI (US); Mathieu Sylvain, Mascouche (CA); Joe Daniels, Middleton, WI (US)

(21) Appl. No.: 19/053,289

(22) Filed: Feb. 13, 2025

(51) Int. Cl. G06Q 30/0601; G06T 17/00

(52) U.S. Cl. CPC G06F 30/13; G06Q 30/0621; G06Q 30/0643; G06T 17/00

(57) ABSTRACT

A processor-based shoppable visual pipeline has a 3D modeling engine and a material calculating engine. The pipeline receives user product selections for building materials that are represented in a 3D visual model for a home, building or structure. The pipeline generates, by the 3D modeling engine, a rendered 3D visual model of the home, building or structure based on the 3D visual model. The pipeline generates, by the material calculating engine, one or more building materials files that list building materials or products corresponding to the user product selections and the representations thereof in the 3D visual model for the home, building or structure, for user purchase consideration.

### FIELD

The technical field of the present disclosure relates to e-commerce, computer-based tools for building design and building materials, building information modeling (BIM) technology, visualization and estimation technology, computer aided design (CAD), and/or computer-based pipeline technology.

### BACKGROUND

Computer-based tools exist for use in design, construction or remodeling, of a home, building or other structure. There are e-commerce sites for selection and purchasing of building materials and products. These technological resources presently provide a limited connection between visualization of a home and the materials necessary to build or modify the home. Therefore, there is a need in the art for a solution which improves upon this limited connection.

### SUMMARY

Various embodiments of an estimation and visualization pipeline, which may be used for visualization of a home, building or other structure and estimation of price or cost for building materials and products, are described herein. In some embodiments, a method is performed by a processor-based shoppable visual pipeline and includes receiving user product selections for building materials that are represented in a 3D visual model for a structure. The method also includes generating, by a 3D modeling engine, a rendered 3D visual model of the structure based on the 3D visual model. The method includes generating, from the 3D visual model and by a material calculating engine, one or more building materials files that list building materials or products corresponding to the product selections and the representations thereof in the 3D visual model for the structure, for user purchase consideration.

Other aspects and advantages of the embodiments will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments. Some embodiments may include fewer or more components than those shown in the figures.

FIG. 1 illustrates a system in which some example embodiments may be used for improved builder project management.

FIG. 2 illustrates a schematic block diagram of example circuitry embodying a device that may perform various operations in accordance with some example embodiments described herein.

FIG. 3 illustrates a schematic block diagram of example circuitry embodying a device that may perform various operations in accordance with some example embodiments described herein.

FIG. 4 illustrates some embodiments of a shoppable visual pipeline, or estimation and visualization pipeline, for use in visualization of a home and generation of a shoppable list of materials desired to build or modify that home.

FIG. 5 illustrates some embodiments of a user interface suitable for use in the shoppable visual pipeline of FIG. 4 and further embodiments.

FIG. 6 illustrates some embodiments round-trip processing of an architectural detail file which may be used in a variation of the shoppable visual pipeline of FIG. 4.

FIG. 7 is a flow diagram illustrating some embodiments of a technological method that may be performed by embodiments of a shoppable visual pipeline as described herein, and variations thereof.

FIG. 8 is a further flow diagram illustrating some embodiments of a technological method that may be performed by embodiments of a shoppable visual pipeline as described herein, and variations thereof.

### DETAILED DESCRIPTION

Some example embodiments will now be described more fully hereinafter with reference to the accompanying figures, in which some, but not necessarily all, embodiments are shown. Because inventions described herein may be embodied in many different forms, the invention should not be limited solely to the embodiments set forth herein; rather, these embodiments are provided so that this disclosure will satisfy applicable legal requirements.

The term “computing device” is used herein to refer to any one or all of programmable logic controllers (PLCs), programmable automation controllers (PACs), industrial computers, desktop computers, personal data assistants (PDAs), laptop computers, tablet computers, smart books, palm-top computers, personal computers, smartphones, wearable devices (such as headsets, smartwatches, or the like), and similar electronic devices equipped with at least a processor and any other physical components necessarily to perform the various operations described herein. Devices such as smartphones, laptop computers, tablet computers, and wearable devices are generally collectively referred to as mobile devices.

The term “server” or “server device” is used to refer to any computing device capable of functioning as a server, such as a master exchange server, web server, mail server, document server, or any other type of server. A server may be a dedicated computing device or a server module (e.g., an application) hosted by a computing device that causes the computing device to operate as a server.

Described herein are various embodiments of computer-based tools, pipelines, systems and related technological processes or methods that are used in estimation and visualization, and shopping, e.g., e-commerce shopping, for building materials and products to be used in building or modifying a home, building or other structure. Various embodiments support user interaction with selection of building materials or products, generation of the rendered 3D visual model of a home, building or other structure using the selected building materials or products, and generation of building materials files, for example that have quantities and costs of these user-selected building materials or products. By integrating building materials selection, building design visualization, and building materials purchasing, various embodiments present a technological solution and technological improvement in the limited connection between visualization of a home and the materials necessary to build or modify the home, as otherwise available in disparate and limited technological tools. Such technological improvement(s) benefit designers, builders, merchants and customers using building materials and products.

In various embodiments, a shoppable visual pipeline is able to take a 3D visual model (or a 2D set of data that represents a 3D model) that illustrates a home (or other building structure) and generate a shoppable SKU (stock keeping unit) or other merchandise information for selected building materials and products. That is, the shoppable visual pipeline uses geometric data (2D or 3D) of building materials and products, calculates material quantities based on the product selections that have been made by a user that are in a visualization depicting the products appearing on or in the home, and then generates a material list (i.e., a list of selected building materials and products, SKU list, etc.) that the user can consider and purchase. In some embodiments, the shoppable visual pipeline determines prices of the selected building materials and products, for the material list, via pricelists and/or catalogs from manufacturers and/or distributors.

The shoppable visual pipeline includes product selection using geometric data from a 3D visualization model or from a 2D set of data, calculates material quantities, and associates those quantities of each product and its SKU or other product identifier, which is then used to obtain pricing. In other words, the pipeline is architected to examine manufacturer part data and the attributes of the product information associated with it, and uses that for material calculation purposes for quantities and costs (e.g., by a material calculation engine).

In some embodiments, the product data comes from a product information management system, which provides the attribute set that can be incorporated in the shoppable SKU automatically. Furthermore, in some embodiments, the attribute set can be updated automatically. For example, if a user selects to change the roofing for a building project, the pipeline can provide a materials list for the change with an updated price that corresponds to the change in the roofing. In some embodiments, the pipeline provides a visualization that allows for obtaining an updated qualitative material list every time a change is made to, entered into, and/or saved in the visualization.

In some embodiments, the pipeline uses an architectural detail file (e.g., an Autodesk Revit file) that contains architectural details related to the design of the home or structure (e.g., 3D model, elevation details, floor plans, project settings, and other similar elements, etc.). In some embodiments, the architectural detail file has an identifier (ID) (e.g., a Revit ID) for every object in the file. The pipeline generates the architectural detail file and exports it to a standard file format, such as IFC (International Foundation Class), thereby creating an IFC file. The system loads the IFC file into building component design software that sends cut instructions to size building materials used to manufacture a home (or other structure). The output of the software is a component design file. The component design file preserves the IDs (e.g., Revit IDs) for the objects in the IFC file. In some embodiments, the system exports that file is exported as an IFC file and merges with the architectural detail file, brought back into Revit, where it may be reprocessed by the pipeline when performing visualization and estimating again. In some embodiments, this reprocessing occurs, for example, after changes to the design and visualization of structure are made. For example, multiple iterations for estimating may be required when framing changes occur. For example, when the iterated, merged architectural detail file comes back in for reprocessing, it indicates wall₁ is still wall₁, but there is additional information for the changes, and the system and process are able to use those IDs between the two revisions.

For various embodiments and variations thereof, it is noted that files using IFC file format are Building Information Modeling (BIM) files. IFC files are platform neutral or independent. Other BIM file formats, such as Revit file format, may be platform specific.

### System Architecture

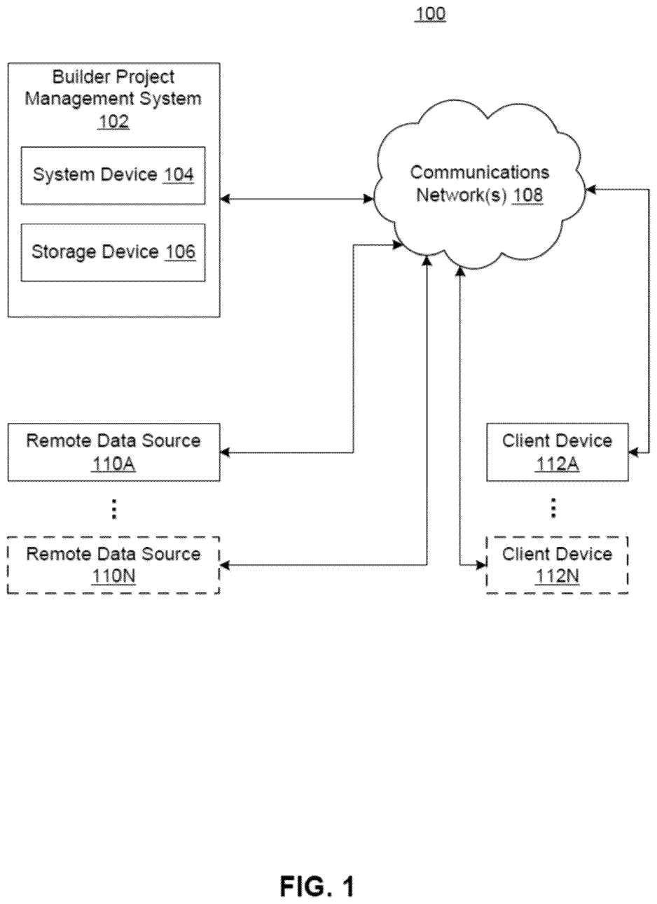

Example embodiments described herein may be implemented using any of a variety of computing devices or servers. To this end, FIG. 1 illustrates an example environment within which various embodiments may operate. As illustrated, a builder project management system 102 may include a system device 104 in communication with a storage device 106. Although system device 104 and storage device 106 are described in singular form, some embodiments may utilize more than one system device 104 and/or more than one storage device 106. Additionally, some embodiments of the builder project management system 102 may not require a storage device 106 at all. Whatever the implementation, the builder project management system 102, and its constituent system device(s) 104 and/or storage device(s) 106 may receive and/or transmit information via communications network 108 (e.g., the Internet) with any number of other devices, such as one or more of remote data sources 110A through 110N and/or one or more client devices 112A through 112N.

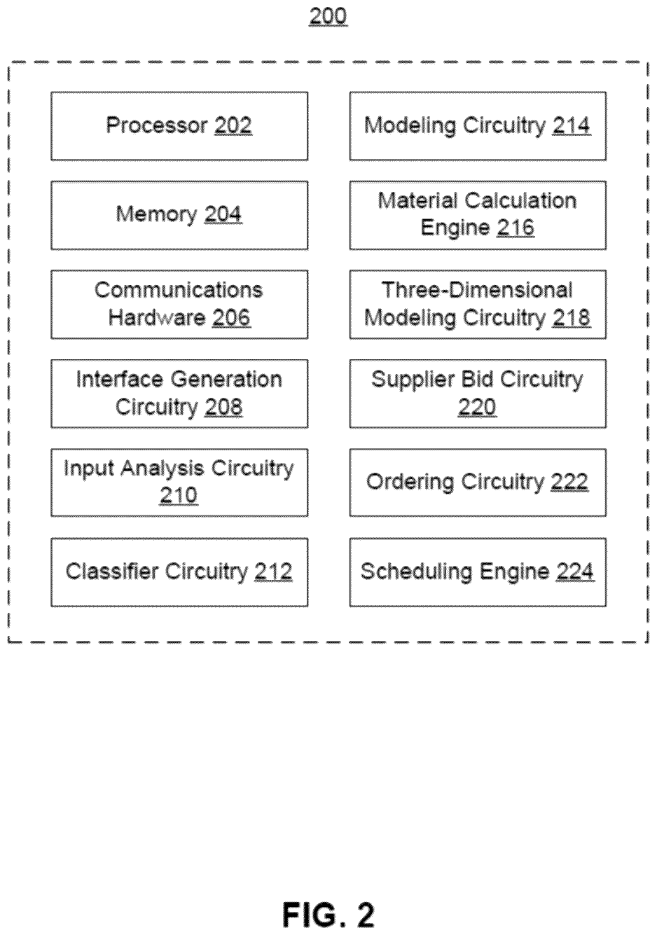

System device 104 may be implemented as one or more servers, which may or may not be physically proximate to other components of builder project management system 102. Furthermore, some components of system device 104 may be physically proximate to the other components of builder project management system 102 while other components are not. System device 104 may receive, process, generate, and transmit data, signals, and electronic information to facilitate the operations of the builder project management system 102. Particular components of system device 104 are described in greater detail below with reference to apparatus 200 in connection with FIG. 2.

Storage device 106 may comprise a distinct component from system device 104, or may comprise an element of system device 104 (e.g., memory 204, as described below in connection with FIG. 2). Storage device 106 may be embodied as one or more direct-attached storage (DAS) devices (such as hard drives, solid-state drives, optical disc drives, or the like) or may alternatively comprise one or more Network Attached Storage (NAS) devices independently connected to a communications network (e.g., communications network 108). Storage device 106 may host the software executed to operate the builder project management system 102. Storage device 106 may store information relied upon during operation of the builder project management system 102, such as various models that may be used by the builder project management system 102, data and documents (e.g., blueprint datasets) to be analyzed using the builder project management system 102, or the like. In addition, storage device 106 may store control signals, device characteristics, and access credentials enabling interaction between the builder project management system 102 and one or more of the remote data sources 110A-110N or client devices 112A-112N.

The one or more remote data sources 110A-110N may be embodied by any storage devices known in the art. Similarly, the one or more client devices 112A-112N may be embodied by any computing devices known in the art, such as desktop or laptop computers, tablet devices, smartphones, or the like. The one or more remote data sources 110A-110N and the one or more client devices 112A-112N need not themselves be independent devices, but may be peripheral devices communicatively coupled to other computing devices.

Although FIG. 1 illustrates an environment and implementation in which the builder project management system 102 interacts with one or more of remote data sources 110A-110N and/or client devices 112A-112N, in some embodiments users may directly interact with the builder project management system 102 (e.g., via input/output circuitry of system device 104), in which case a separate client device may not be utilized. Whether by way of direct interaction or via a separate client device, a user may communicate with, operate, control, modify, or otherwise interact with the builder project management system 102 to perform the various functions and achieve the various benefits described herein.

### Example Implementing Apparatuses

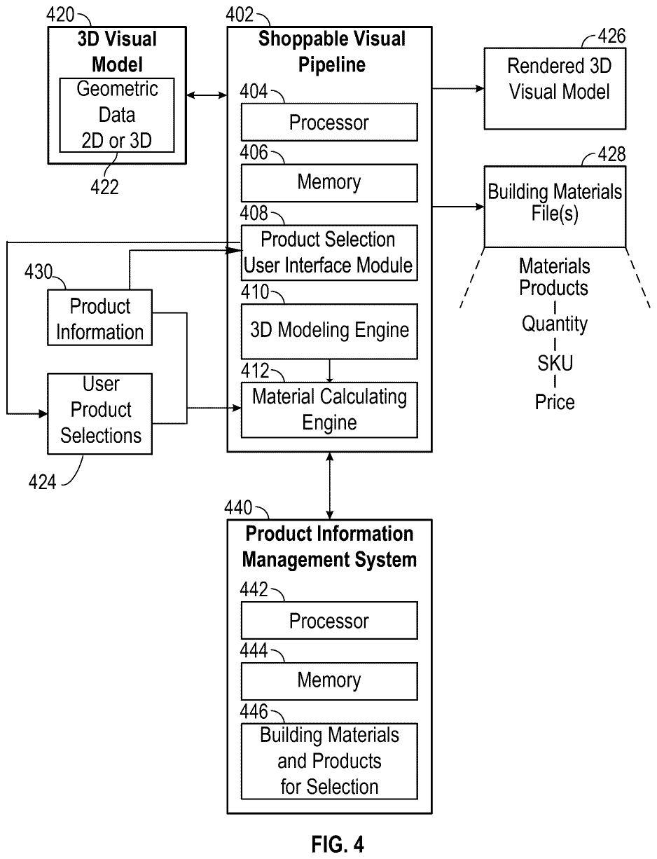

System device 104 of the builder project management system 102 (described previously with reference to FIG. 1) may be embodied by one or more computing devices or servers, shown as apparatus 200 in FIG. 2. As illustrated in FIG. 2, the apparatus 200 may include processor 202, memory 204, communications hardware 206, interface generation circuitry 208, input analysis circuitry 210, classifier circuitry 212, modeling circuitry 214, a material calculation engine 216, three-dimensional modeling circuitry 218, supplier bid circuitry 220, ordering circuitry 222, and a scheduling engine 224, each of which will be described in greater detail below. The various components illustrated in FIG. 2 may each be connected with processor 202, though in some embodiments, the apparatus 200 may further comprise a bus (not expressly shown in FIG. 2) for passing information amongst any combination of the various components of the apparatus 200. The apparatus 200 may be configured to execute various operations described above in connection with FIG. 1 and below in connection with FIGS. 4-8.

The processor 202 (and/or co-processor or any other processor assisting or otherwise associated with the processor) may be in communication with the memory 204 via a bus for passing information amongst components of the apparatus. The processor 202 may be embodied in a number of different ways and may, for example, include one or more processing devices configured to perform independently. Furthermore, the processor may include one or more processors configured in tandem via a bus to enable independent execution of software instructions, pipelining, and/or multithreading. The use of the term “processor” may be understood to include a single core processor, a multi-core processor, multiple processors of the apparatus 200, remote or “cloud” processors, or any combination thereof.

The processor 202 may be configured to execute software instructions stored in the memory 204 or otherwise accessible to the processor (e.g., software instructions stored on a separate storage device 106, as illustrated in FIG. 1). In some cases, the processor may be configured to execute hard-coded functionality. As such, whether configured by hardware or software methods, or by a combination of hardware with software, the processor 202 represent an entity (e.g., physically embodied in circuitry) capable of performing operations according to various embodiments of the present invention while configured accordingly. Alternatively, as another example, When the processor 202 is embodied as an executor of software instructions, the software instructions may specifically configure the processor 202 to perform the algorithms and/or operations described herein when the software instructions are executed.

Memory 204 is non-transitory and may include, for example, one or more volatile and/or non-volatile memories. In other words, for example, the memory 204 may be an electronic storage device (e.g., a computer readable storage medium). The memory 204 may be configured to store information, data, content, applications, software instructions, or the like, for enabling the apparatus to carry out various functions in accordance with example embodiments contemplated herein.

The communications hardware 206 may be any means such as a device or circuitry embodied in either hardware or a combination of hardware and software that is configured to receive and/or transmit data from/to a network and/or any other device, circuitry, or module in communication with the apparatus 200. In this regard, the communications hardware 206 may include, for example, a network interface for enabling communications with a wired or wireless communication network. For example, the communications hardware 206 may include one or more network interface cards, antennas, buses, switches, routers, modems, and supporting hardware and/or software, or any other device suitable for enabling communications via a network. Furthermore, the communications hardware 206 may include the processing circuitry for causing transmission of such signals to a network or for handling receipt of signals received from a network.

The communications hardware 206 may further be configured to provide output to a user and, in some embodiments, to receive an indication of user input. In this regard, the communications hardware 206 may comprise a user interface, such as a display, and may further comprise the components that govern use of the user interface, such as a web browser, mobile application, dedicated client device, or the like. In some embodiments, the communications hardware 206 may include a keyboard, a mouse, a touch screen, touch areas, soft keys, a microphone, a speaker, and/or other input/output mechanisms. The communications hardware 206 may utilize the processor 202 to control one or more functions of one or more of these user interface elements through software instructions (e.g., application software and/or system software, such as firmware) stored on a memory (e.g., memory 204) accessible to the processor 202.

In addition, the apparatus 200 further comprises interface generation circuitry 208 that generates a builder project management user interface (UI) and other various user interfaces associated with the builder project management system 102. The interface generation circuitry 208 may utilize processor 202, memory 204, or any other hardware component included in the apparatus 200 to perform these operations, as described in connection with at least FIGS. 4-8 below. The interface generation circuitry 208 may further utilize communications hardware 206 to gather data from a variety of sources (e.g., client devices 112A-112N, remote data sources 110A-110N, and/or storage device 106, as shown in FIG. 1) and/or to receive data from a user, and in some embodiments may utilize processor 202 and/or memory 204 to configure and generate a builder project management UI and various different views within the builder project management UI.

In addition, the apparatus 200 further comprises input analysis circuitry 210 that processes one or more files (e.g., a blueprint dataset) provided as input to the builder project management system 102. The input analysis circuitry 210 may utilize processor 202, memory 204, or any other hardware component included in the apparatus 200 to perform these operations, as described in connection with FIGS. 4-8 below. The input analysis circuitry 210 may further utilize communications hardware 206 to gather data from a variety of sources (e.g., client devices 112A-112N as shown in FIG. 1), and/or exchange data with a user, and in some embodiments may utilize processor 202 and/or memory 204 to pre-process a blueprint dataset, including, for example, converting a blueprint dataset from a first file format to a second file format.

In addition, the apparatus 200 further comprises classifier circuitry 212 that classifies portions of a blueprint dataset received by the builder project management system 102. To do so, the classifier circuitry 212 may include a classifier model (or multiple classifier models) trained to identify different pages or portions of a blueprint dataset. For example, the classifier model may be trained to distinguish a floorplan from an elevation diagram contained within a blueprint dataset and label the identified portions as such. The classifier circuitry 212 may utilize processor 202, memory 204, or any other hardware component included in the apparatus 200 to perform these operations, as described in connection with FIG. 4-8 below. The classifier circuitry 212 may further utilize communications hardware 206 to gather data from a variety of sources (e.g., storage device 106 and/or client devices 112A-112N as shown in FIG. 1), and in some embodiments may utilize processor 202 and/or memory 204 to classify a respective portion of a blueprint dataset for a structure as a respective portion of the structure.

In addition, the apparatus 200 further comprises modeling circuitry 214 that generates digitized feature datasets for classified portions of a blueprint dataset. The modeling circuitry 214 may utilize processor 202, memory 204, or any other hardware component included in the apparatus 200 to perform these operations, as described in connection with FIG. 4 below. In some embodiments, the modeling circuitry 214 may further utilize communications hardware 206 to gather data from a variety of sources (e.g., client devices 112A-112N, remote data sources 110A-110N, and/or storage device 106, as shown in FIG. 1). In some embodiments, the modeling circuitry 216 may comprise multiple models, such as machine learning (ML) models (e.g., supervised or unsupervised ML models), artificial intelligence (AI) reasoning models, and/or the like which are utilized to generate output data (e.g., digitized feature datasets comprising line and measurement data for respective portions of a blueprint dataset) based on corresponding input data (e.g., a respective classified portion of a blueprint dataset) provided to the model. In this regard, each model used may be specially trained to recognize and label features and determine measurements and sizing information for a particular portion of a blueprint dataset. For instance, one model may be specially trained to identify roofing features and may be provided a roofing diagram of the blueprint dataset. Likewise, another model may be specially trained to identify siding features and may be provided an elevation diagram of the blueprint dataset as input. The siding model may then process the elevation diagram and identify regions which would include siding along with measurements and other sizing information for the siding. Other models may be specially trained to identify and provide information on other aspects of a structure, such as doors, windows, and/or the like.

In addition, the apparatus 200 further comprises a material calculation engine 216 that generates material pack datasets based on digitized feature datasets. The material calculation engine 216 may utilize processor 202, memory 204, or any other hardware component included in the apparatus 200 to perform these operations, as described below. The material calculation engine 216 may further utilize communications hardware 206 to gather data from a variety of sources (e.g., storage device 106 and/or remote data sources 110A-110N as shown in FIG. 1), and in some embodiments may utilize processor 202 and/or memory 204 to generate material pack datasets. A material pack dataset may comprise data representing materials (e.g., all materials) needed for building a portion of the structure associated with a respective digitized feature dataset. For example, the material calculation engine 216 may generate a material pack dataset that includes data representing materials needed for building a roof based on a digitized feature dataset that includes line and measurement information for the roof. In various embodiments as described herein, the material calculation engine 216 may employ a plurality of algorithms, formulas, and the like for determining an exact number of materials needed for building a particular section of a home. Advantageously, the material calculation engine 216 may be configured to not only output an amount of material needed, but also indicate a specific use for the material. In this regard, output of the material calculation engine 216 may be logically organized, wherein certain materials are tagged for certain uses. As one example, rather than merely indicating that 180 pieces of 2×4 lumber are needed for a certain section of a house, the material calculation engine 216 may be configured to indicate that x pieces of 2×4 lumber are needed for bracing, y pieces of 2×4 lumber are needed for wall plates, etc. As further described below, the material calculation engine 216 may also be configured to map materials to supplier stock keeping units (SKUs), thereby providing a downstream shopping experience for the builder directly by way of the builder project management UI.

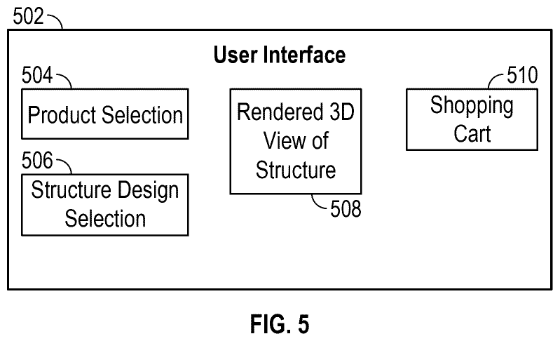

In addition, the apparatus 200 further comprises three-dimensional modeling circuitry 218 that generates a three-dimensional (3D) model of a structure based on digitized feature datasets (e.g., as generated by the modeling circuitry 214). To do so, the three-dimensional modeling circuitry 218 may include various algorithms (such as one or more machine learning techniques) that are configured to generate and render a 3D model from two-dimensional (2D) image data. The three-dimensional modeling circuitry 218 may utilize processor 202, memory 204, or any other hardware component included in the apparatus 200 to perform these operations, as described in connection with FIG. 5 below. The three-dimensional modeling circuitry 218 may further utilize communications hardware 206 to gather data from a variety of sources (e.g., storage device 106 and/or client devices 112A-112N as shown in FIG. 1), and in some embodiments may utilize processor 202 and/or memory 204 to generate a 3D model of a structure.

In addition, the apparatus 200 further comprises supplier bid circuitry 220 that retrieves and applies pricing information to material pack datasets based on supplier inventory data. The supplier bid circuitry 220 may utilize processor 202, memory 204, or any other hardware component included in the apparatus 200 to perform these operations. The supplier bid circuitry 220 may further utilize communications hardware 206 to gather data from a variety of sources (e.g., remote data sources 110A-110N or storage device 106, as shown in FIG. 1), and in some embodiments may utilize processor 202 and/or memory 204 to retrieve and apply pricing information to material pack datasets. In some embodiments, the supplier bid circuitry 220 may comprise a web scraper configured to scrape supplier websites and retrieve pricing information for specific materials (e.g., based on a SKU). In some embodiments, the supplier bid circuitry 220 may be configured to store pricing information of various SKUs from various suppliers and maintain an updated record of pricing information by automatically scraping supplier websites for updated pricing information periodically. In some embodiments, the supplier bid circuitry 220 may be configured to receive pricing information transmitted to the builder project management system 102 from supplier systems. In this regard, in some embodiments, the builder project management system 102 may be configured to allow supplier systems to submit bids for material pack datasets. In other words, supplier may offer pricing on various packs of materials by way of the builder project management system 102, such that a user of the builder project management system 102 may be presented with several options of pricing for a set of materials.

In addition, the apparatus 200 further comprises ordering circuitry 222 that executes orders of materials associated with material pack datasets. The ordering circuitry 222 may utilize processor 202, memory 204, or any other hardware component included in the apparatus 200 to perform these operations. The ordering circuitry 222 may further utilize communications hardware 206 to gather data from a variety of sources (e.g., remote data sources 110A-110N or storage device 106, as shown in FIG. 1), and in some embodiments may utilize processor 202 and/or memory 204 to execute orders of materials in response to user interactions with the builder project management UI.

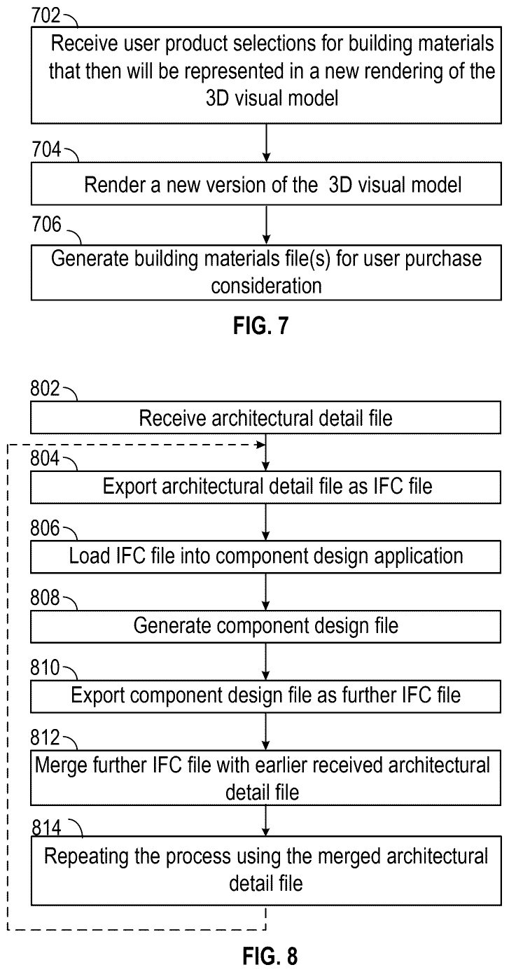

In addition, the apparatus 200 further comprises a scheduling engine 224 that a generates a recommended delivery schedule for materials associated with one or more material pack datasets. The scheduling engine 224 may utilize processor 202, memory 204, or any other hardware component included in the apparatus 200 to perform these operations, as described in connection with FIG. 7 below. The scheduling engine 224 may further utilize communications hardware 206 to gather data from a variety of sources (e.g., remote data sources 110A-110N, client devices 112A-112N, and/or storage device 106, as shown in FIG. 1), and in some embodiments may utilize processor 202 and/or memory 204 to generate a recommended delivery schedule and schedule deliveries based on various sources of data (further described herein).

Although components 202-224 are described in part using functional language, it will be understood that the particular implementations necessarily include the use of particular hardware. It should also be understood that certain of these components 202-224 may include similar or common hardware. For example, the interface generation circuitry 208, input analysis circuitry 210, classifier circuitry 212, modeling circuitry 214, material calculation engine 216, three-dimensional modeling circuitry 218, supplier bid circuitry 220, ordering circuitry 222, and scheduling engine 224 may each at times leverage use of the processor 202, memory 204, or communications hardware 206 such that duplicate hardware is not required to facilitate operation of these physical elements of the apparatus 200 (although dedicated hardware elements may be used for any of these components in some embodiments, such as those in which enhanced parallelism may be desired). Use of the terms “circuitry,” and “engine” with respect to elements of the apparatus therefore shall be interpreted as necessarily including the particular hardware configured to perform the functions associated with the particular element being described. Of course, while the terms “circuitry” and “engine” should be understood broadly to include hardware, in some embodiments, the terms “circuitry” and “engine” may in addition refer to software instructions that configure the hardware components of the apparatus 200 to perform the various functions described herein.

Although the interface generation circuitry 208, input analysis circuitry 210, classifier circuitry 212, modeling circuitry 214, material calculation engine 216, three-dimensional modeling circuitry 218, supplier bid circuitry 220, ordering circuitry 222, and scheduling engine 224 may leverage processor 202, memory 204, communications circuitry 206, or input-output circuitry 208 as described above, it will be understood that any of these elements of apparatus 200 may include one or more dedicated processor, specially configured field programmable gate array (FPGA), or application specific interface circuit (ASIC) to perform its corresponding functions, and may accordingly leverage processor 202 executing software stored in a memory (e.g., memory 204), or memory 204, communications circuitry 206 or input-output circuitry 208 for enabling any functions not performed by special-purpose hardware elements. In all embodiments, however, it will be understood that the interface generation circuitry 208, input analysis circuitry 210, classifier circuitry 212, modeling circuitry 214, material calculation engine 216, three-dimensional modeling circuitry 218, supplier bid circuitry 220, ordering circuitry 222, and scheduling engine 224 are implemented via particular machinery designed for performing the functions described herein in connection with such elements of apparatus 200.

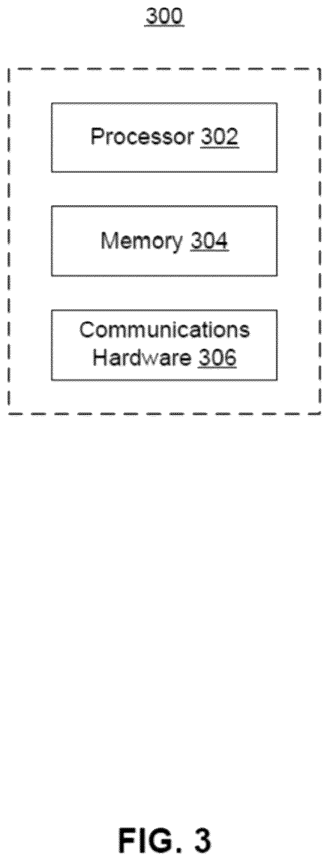

As illustrated in FIG. 3, an apparatus 300 is shown that represents an example client device (e.g., any of client devices 112A-112N). The apparatus 300 includes processor 302, memory 304, and communications hardware 306, each of which is configured to be similar to the similarly named components described above in connection with FIG. 2.

In some embodiments, various components of the apparatuses 200 and 300 may be hosted remotely (e.g., by one or more cloud servers) and thus need not physically reside on the corresponding apparatus 200 or 300. Thus, some or all of the functionality described herein may be provided by third party circuitry. For example, a given apparatus 200 or 300 may access one or more third party circuitries via any sort of networked connection that facilitates transmission of data and electronic information between the apparatus 200 or 300 and the third party circuitries. In turn, that apparatus 200 or 300 may be in remote communication with one or more of the other components describe above as comprising the apparatus 200 or 300.

As will be appreciated based on this disclosure, example embodiments contemplated herein may be implemented by an apparatus 200 or 300. Furthermore, some example embodiments may take the form of a computer program product comprising software instructions stored on at least one non-transitory computer-readable storage medium (e.g., memory 204). Any suitable non-transitory computer-readable storage medium may be utilized in such embodiments, some examples of which are non-transitory hard disks, CD-ROMs, flash memory, optical storage devices, and magnetic storage devices. It should be appreciated, with respect to certain devices embodied by apparatus 200 as described in FIG. 2 or apparatus 300 as described in FIG. 3, that loading the software instructions onto a computing device or apparatus produces a special-purpose machine comprising the means for implementing various functions described herein.

### Examples of Shoppable Visual Pipelines

The system architecture of FIG. 1 can be configured to operate a shoppable visual pipeline. FIG. 4 illustrates some embodiments of a shoppable visual pipeline 402, or estimation and visualization pipeline, for use in visualization of a home and generation of a shoppable list of materials desired to build or modify that home. Implementation of the shoppable visual pipeline 402 as a computer-based tool or computer-based system may be accomplished through programming and software, for example an application, software executing on a processor, firmware, hardware, or combinations thereof, by a person of skill in the art. In some embodiments, the shoppable visual pipeline 402 has a processor 404, a memory 406, a product selection user interface module 408, a 3D modeling engine 410, and a material calculating engine 412. The product selection user interface module 408 generates a user interface, which can be communicated to a user device such as a computer or smart phone, etc., for user interaction as further described with reference to FIG. 5. User product selections 424, for example made through a user interface, are communicated to the shoppable visual pipeline 402 through the product selection user interface module 408, for example by network connection and appropriate communication protocols.

A 3D visual model 420, which has geometric data 422, e.g., 2D or 3D geometric data, is populated through user interaction, using user product selections 424 of building materials or products. In some embodiments, these user product selections 424 are informed through product information 430 and communication with a product information management system 440, for example an e-commerce system with available data of building materials and products for selection 446. The product information 430 can be supplied from and/or made accessible by one or more vendors. This information can be stored in memory. While the product information 430 is not part of the shoppable visual pipeline 402 in some embodiments, in some other embodiments, the product information 430 is part of the shoppable visual pipeline 402. The product information management system 440 has a processor 442 and a memory 444, and may have appropriate e-commerce or other merchandising, manufacturing, distributing, etc., support (not shown), as readily devised.

From the 3D visual model 420, the 3D modeling engine 410 renders a new version of a 3D visual model 426, and the material calculating engine 412 generates building material file(s) 428. In some embodiments, the rendered 3D visual model 426 is communicated through the product selection user interface module 408 for viewing by a user. In some embodiments, the building material file(s) 428 is communicated through the product selection user interface module 408 for review and shopping by a user. For example, the building materials file(s) could include a list of materials or products, each with an indication of quantity, a corresponding SKU (shop keeping unit) or other product identifier, a corresponding price of the item and total price for the building materials represented in the file. In other words, the material calculating engine 412 is able assign a corresponding SKU (shop keeping unit) or other product identifier, along with the other details to each of the materials on the list. The materials calculating engine 412 receives and/or accesses the product information 430 and uses this information in calculating, according to the product selections made by a user, the building materials needed for the building, home or other structure associated with the rendered 3D visual model 426. With this technological tool and these generated outputs, the user is enabled to view the rendered 3D visual model 426 (e.g., of a building, home or other structure) that has the selected building materials or products in place, and is enabled to view the contents of the building materials file(s) 428, including selected materials or products, quantities, SKUs and prices. The user may iterate selections, make changes, or otherwise update the design or materials, and each time view the updated rendered model and the updated materials list. Some versions feature revision tracking.

FIG. 5 illustrates some embodiments of a user interface 502 suitable for use in the shoppable visual pipeline 402 of FIG. 4. For example, the user may view and interact with the user interface 502 on a user device, such as, for example, a computer or smart phone, making product selection 504 and making structure design selection 506 through fixed, hierarchical or drop-down menus, hot buttons, command line interface, or other graphical user interface (GUI) elements to input user selections readily devised. Upon making such selections, or alternatively upon a further selection or entry, the shoppable visual pipeline 402 generates the rendered 3D visual model 426 (see FIG. 4), communicates the same to the user interface 502 to enable the user is able to view the rendered 3D view of structure 208 on the user interface 502. Also, the user is able to view the contents of the shopping cart 510, as is commonly done on e-commerce platforms and readily devised, and here is able to view the contents of the building materials file(s) 428 (see FIG. 4).

Variations on the user interface 502 with further features, coupling to other apps, other systems or other data sources, are readily devised. For example, the user interface 502 could include provisions for uploading or transferring data, printing, communication with building contractors and/or building materials suppliers, communication with one or more cloud services, etc.

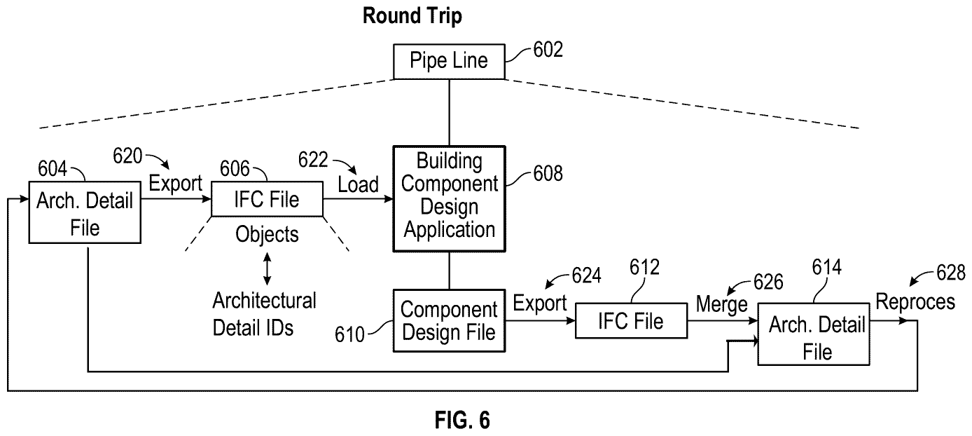

FIG. 6 is a data flow diagram of some embodiments of round-trip processing of an architectural detail file, which may be used in a variation of the shoppable visual pipeline 402 of FIG. 4, in order to process and reprocess an architectural detail file 604 in a pipeline 602. In some embodiments, the architectural detail file 604 is a Revit file is a specific BIM file format that is platform specific, to Autodesk. Further embodiments, using IFC files and/or other BIM file formats that are specific to other platforms, are understood. In various embodiments, the pipeline 602 could be the shoppable visual pipeline 402 or variation thereof, could be included in the shoppable visual pipeline 402 or variation thereof, or could be a distinct processor-based pipeline coupled to the shoppable visual pipeline 402 or variation thereof.

In the pipeline 602, the architectural detail file 604 is initially an input, and may later be reprocessed, e.g., with iteration(s) based on user selection. The pipeline 602 executes an export 620 action, exporting the architectural detail file 604 as an IFC file 606, which includes objects associated to IDs of the objects in the file. For example, the objects are building materials, as selected by the user and/or automatically selected based on predefined design rules and/or preferences. In some embodiments, this IFC file 606 is associated to, coordinated with, or is a version of the building materials file(s) 428 (see FIG. 4).

Executing a load 622 action, the pipeline 602 loads the IFC file 606 into a building component design application 608, or other component design engine. The building component design application 608 generates a component design file 610, which includes instructions for cut to size building materials that are used to manufacture a home or other structure. For example, the instructions for cutting and sizing may be based on user input and associated dimensions, and sourced from the 3D visual model 420 as viewed in the rendered 3D visual model 426 (see FIG. 4). The building component design application 608 is user interactive, and here the user may make design additions, changes or revisions. The pipeline 602 performs an export action 624 to export the component design file 610 as an IFC file 612. In scenarios where the user has made design additions, changes or revisions, the newly exported IFC file 612 is revised from the originally loaded IFC file 606. This provides opportunity for revising the architectural detail file 604, as follows.

With that newly exported IFC file 612, the pipeline performs a merge 626 action, and merges the IFC file 612 with the earlier input architectural detail file 604, form a merged Revit file 614. The newly merged Revit file 614 is submitted for a reprocess 628 action, and may be iterated through the pipeline 602 as a revision of the original architectural detail file 604. Some versions feature revision tracking, for example in association with object IDs. Some versions feature integration with and/or access with the product attribute information used to generate the shoppable SKU.

In some embodiments, the component design file 610 is used for the 3D visual model 420 in the shoppable visual pipeline 102 (see FIG. 4). For example, user product selections 124 could tie into the building component design application 608 for generation of the component design file 610. In turn, the component design file 610, used for the 3D visual model 420, is the source for the shoppable visual pipeline 402 to generate the rendered 3D visual model 426 and the building materials file(s) 428. For example, the building component design application 608 could include the 3D modeling engine and generate the rendered 3D visual model 426, in cooperation with or as part of the shoppable visual pipeline 402. Using the pipeline 602, this process can be reiterated, through reprocessing the architectural detail file 604, 614. Again, user interaction with the building design or user product selections 424 through the building component design application 608 could generate an updated component design file 610, for further iteration and reprocessing of the architectural detail file.

FIG. 7 is a flow diagram illustrating some embodiments of a technological method that may be performed by embodiments of a shoppable visual pipeline as described herein, and variations thereof. In some embodiments, the technological method is performed by processing logic that can include hardware (e.g., circuitry, dedicated logic, memory, etc.), software (such as is run on a general-purpose computer system or a dedicated machine), firmware (e.g., software programmed into a read-only memory), or combinations thereof. The method may be embodied in a processor-based system, or may be embodied in instructions on a tangible, non-transitory computer-readable media.

In processing block 702, processing logic receives user product selections for building materials that then will be represented in a new rendering of the 3D visual model. For example, a processor-based pipeline could receive user product selections, through a user interface. For example, a user could select, create and/or cause transfer of a 3D visual model for a home, building or structure, and make user product selections for building materials, populating the 3D visual model with representations of such selected products. This may occur through a user interface.

In processing block 704, processing logic renders a new version of the 3D visual model that includes the product selections of building materials. In some embodiments, a 3D modeling engine generates the rendered 3D visual model, based on 2D or 3D data of the 3D visual model. The rendered 3D visual model may be displayed through a user interface for user consideration of appearance of the home, building or structure with the selected building materials, i.e., user product selections, in place in the rendered image.

In processing block 706, processing logic generates one or more building materials files. The building materials file(s) list the building materials or products corresponding to the user product selections, which are represented in the rendered 3D visual model for the home, building or structure. In some embodiments, the generated building materials file(s) are for user purchase consideration, for example in an e-commerce context, system or process.

With processing blocks 702, 704, 706, the user is enabled to view a rendered 3D visual model of a home, building or structure, make product selections for building materials, view the selected building materials in the rendered 3D visual model of the home, building or structure, and view a list of the building materials or products (e.g., with description, price, SKU or other product ID), for consideration of purchase.

FIG. 8 is s flow diagram illustrating some embodiments of another technological method that may be performed by embodiments of a shoppable visual pipeline as described herein, and variations thereof. In some embodiments, the technological method is performed by processing logic that can include hardware (e.g., circuitry, dedicated logic, memory, etc.), software (such as is run on a general-purpose computer system or a dedicated machine), firmware (e.g., software programmed into a read-only memory), or combinations thereof. The method may be embodied in a processor-based system, or may be embodied in instructions on a tangible, non-transitory computer-readable media.

In processing block 802, processing logic receives an architectural detail file (e.g., Revit file). For example, the architectural detail file could be selected, created or transferred by a user, through a computer-aided design (CAD) tool, and be a 3D visual model of a home, building or structure. For example, the Revit file is received in a processor-based pipeline.

In processing block 804, processing logic exports the architectural detail file as an IFC file. In some embodiments, the IFC file is platform-independent. For example the processor-based pipeline performs reformatting or format translation and exports the architectural detail file as an IFC file.

In processing block 806, processing logic loads the IFC file into a building component design application. It is understood the IFC file is compatible with the component design application.

In processing block 808, the processor-based pipeline generates a component design file from the loaded IFC file. More specifically, in some embodiments, the building component design application (e.g., executing in or called by the processor-based pipeline) generates a component design file.

In some embodiments combining the methods of FIG. 7 and FIG. 8, it is understood the user may make user product selections, which may populate or modify the component design file.

In processing block 810, processing logic exports the component design file as a further IFC file.

In processing block 812, processing logic merges the further IFC file with the earlier received architectural detail file. This creates a merged architectural detail file.

In embodiments combining the methods of FIG. 7 and FIG. 8, it is understood the user-made product selections, present in the further IFC file, are then propagated to the merged architectural detail file. In turn, the merged architectural detail file, with the user made product selections thus represented in the 3D visual model of a home, building or structure, can be used for generating the rendered 3D visual model of the home, building or structure. The rendered 3D visual model may be viewed with the user product selections of building materials or products in place on or in the home, building or structure.

In processing block 814, the processor-based pipeline repeats the process using the merged architectural detail file. In some embodiments combining the methods of FIG. 7 and FIG. 8, repeating the process with the merged architectural detail file results in generating an updated component design file that may be used for the building materials file(s) or may be used to generate the building materials file(s).

Reprocessing, when used for iteration of the process, processing logic re-enters the flow at the action 804 from processing block 814. Some versions of the flow use revision tracking, which tracks the changes and the reprocessing. For example, revision tracking could use version numbering or revision numbering, as a tracked parameter associated with a design cycle, a product selection cycle, a user-selected interval or stage in a design cycle, etc.

With processing blocks 802, 804, 806, 800 a, 810, 812, 814, the user is enabled to use a platform specific architectural detail file (e.g., Revit file, etc.) and a platform-independent IFC file for coordinated BIM (building information modeling) application(s). For example, in embodiments combining the methods of FIG. 7 and FIG. 8, the user is enabled to make user product selections of building materials or products, view a rendering of a home, building or structure with the selected building materials or products in place, and consider purchase of the selected building materials or products as shown in a list. In some embodiments, all of this occurs through a single user interface. In some embodiments, all of this occurs through one pipeline or two coordinated pipelines, so that the user does not need to use separate, disparate computer-based tools with limited connection between visualization of a home and materials necessary to build or modify the home.

Detailed illustrative embodiments are disclosed herein. However, specific functional details disclosed herein are merely representative for purposes of describing embodiments. Embodiments may, however, be embodied in many alternate forms and should not be construed as limited to only the embodiments set forth herein.

It should be understood that although the terms first, second, etc. may be used herein to describe various steps or calculations, these steps or calculations should not be limited by these terms. These terms are only used to distinguish one step or calculation from another. For example, a first calculation could be termed a second calculation, and, similarly, a second step could be termed a first step, without departing from the scope of this disclosure. As used herein, the term “and/or” and the “/” symbol includes any and all combinations of one or more of the associated listed items.

As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

With the above embodiments in mind, it should be understood that the embodiments might employ various computer-implemented operations involving data stored in computer systems. These operations are those requiring physical manipulation of physical quantities. Usually, though not necessarily, these quantities take the form of electrical or magnetic signals capable of being stored, transferred, combined, compared, and otherwise manipulated. Further, the manipulations performed are often referred to in terms, such as producing, identifying, determining, or comparing. Any of the operations described herein that form part of the embodiments are useful machine operations. The embodiments also relate to a device or an apparatus for performing these operations. The apparatus can be specially constructed for the required purpose, or the apparatus can be a general-purpose computer selectively activated or configured by a computer program stored in the computer. In particular, various general-purpose machines can be used with computer programs written in accordance with the teachings herein, or it may be more convenient to construct a more specialized apparatus to perform the required operations.

A module, an application, a layer, an agent or other method-operable entity could be implemented as hardware, firmware, or a processor executing software, or combinations thereof. It should be appreciated that, where a software-based embodiment is disclosed herein, the software can be embodied in a physical machine such as a controller. For example, a controller could include a first module and a second module. A controller could be configured to perform various actions, e.g., of a method, an application, a layer or an agent.

The embodiments can also be embodied as computer readable code on a tangible non-transitory computer readable medium. The computer readable medium is any data storage device that can store data, which can be thereafter read by a computer system. Examples of the computer readable medium include hard drives, network attached storage (NAS), read-only memory, random-access memory, CD-ROMs, CD-Rs, CD-RWs, magnetic tapes, and other optical and non-optical data storage devices. The computer readable medium can also be distributed over a network coupled computer system so that the computer readable code is stored and executed in a distributed fashion. Embodiments described herein may be practiced with various computer system configurations including hand-held devices, tablets, microprocessor systems, microprocessor-based or programmable consumer electronics, minicomputers, mainframe computers and the like. The embodiments can also be practiced in distributed computing environments where tasks are performed by remote processing devices that are linked through a wire-based or wireless network.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

In various embodiments, one or more portions of the methods and mechanisms described herein may form part of a cloud-computing environment. In such embodiments, resources may be provided over the Internet as services according to one or more various models. Such models may include Infrastructure as a Service (IaaS), Platform as a Service (PaaS), and Software as a Service (SaaS). In IaaS, computer infrastructure is delivered as a service. In such a case, the computing equipment is generally owned and operated by the service provider. In the PaaS model, software tools and underlying equipment used by developers to develop software solutions may be provided as a service and hosted by the service provider. SaaS typically includes a service provider licensing software as a service on demand. The service provider may host the software, or may deploy the software to a customer for a given period of time. Numerous combinations of the above models are possible and are contemplated.

Various units, circuits, or other components may be described or claimed as “configured to” perform a task or tasks. In such contexts, the phrase “configured to” is used to connote structure by indicating that the units/circuits/components include structure (e.g., circuitry) that performs the task or tasks during operation. As such, the unit/circuit/component can be said to be configured to perform the task even when the specified unit/circuit/component is not currently operational (e.g., is not on). The units/circuits/components used with the “configured to” language include hardware—for example, circuits, memory storing program instructions executable to implement the operation, etc. Reciting that a unit/circuit/component is “configured to” perform one or more tasks is expressly intended not to invoke 35 U.S.C. 112, sixth paragraph, for that unit/circuit/component. Additionally, “configured to” can include generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks.

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

What is claimed is:

1. A method, performed by a processor-based shoppable visual pipeline, the method comprising:
receiving user product selections for building materials that are represented in a 3D visual model for a structure;
generating, by a 3D modeling engine, a rendered 3D visual model of the structure based on the 3D visual model; and
generating, by a material calculating engine from the 3D visual model for the structure, one or more building materials files that list building materials or products corresponding to the product selections and the representations thereof in the 3D visual model for the structure, for user purchase consideration.

2. The method of claim 1, further comprising:
generating a user interface of the shoppable visual pipeline, arranged for the user product selections, user viewing of the rendered 3D visual model of the structure, and user viewing of contents of the one or more building materials files that list building materials or products for user purchase consideration.

3. The method of claim 1, wherein the one or more building materials files include descriptions of the building materials or products, quantities thereof, SKU (stock keeping unit) or other ID thereof, and prices thereof.

4. The method of claim 1, wherein the one or more building materials files include description of at least one of the building materials or products and cutting dimensions thereof.

5. The method of claim 1, further comprising:
iterating the receiving user product selections, the generating a rendered 3D visual model of the home, building or structure, and the generating one or more building materials files, with revision tracking.

6. The method of claim 1, further comprising:
receiving an architectural detail file into a processor-based pipeline;
exporting the architectural detail file as an IFC (International Foundation Class) file;
loading the IFC file into a component design application;
generating a component design file, from the loaded IFC file;
exporting the component design file as a further IFC file; and
merging the further IFC file with the earlier received architectural detail file, to form a merged architectural detail file.

7. The method of claim 6, further comprising:
reprocessing in the processor-based pipeline, with the merged architectural detail file.

8. The method of claim 6, wherein:
the architectural detail file or the merged architectural detail file is used for the 3D visual model; and
the component design file is used for generating the one or more building materials files.

9. A tangible, non-transitory, computer-readable media having instructions thereupon which, when executed by a processor, cause the processor to perform:
receiving into a processor-based shoppable visual pipeline, user product selections for building materials that are represented in a 3D visual model for a structure;
generating, by a 3D modeling engine, a rendered 3D visual model of the structure based on the 3D visual model; and
generating, from the 3D visual model of the structure and by a material calculating engine, one or more building materials files that list building materials or products corresponding to the product selections and the representations thereof in the 3D visual model for the structure, for user purchase consideration.

10. The tangible, non-transitory, computer-readable media of claim 9, wherein the instructions further cause the processor to perform:
generating a user interface of the shoppable visual pipeline, arranged for the user product selections, user viewing of the rendered 3D visual model of the home, building or structure, and user viewing of contents of the one or more building materials files that list building materials or products for user purchase consideration.

11. The tangible, non-transitory, computer-readable media of claim 9, wherein:
the one or more building materials files include descriptions of the building materials or products, quantities thereof, SKU (stock keeping unit) or other ID thereof, and prices thereof; and
the one or more building materials files include description of at least one of the building materials or products and cutting dimensions thereof.

12. The tangible, non-transitory, computer-readable media of claim 9, wherein the instructions further cause the processor to perform;
iterating the receiving user product selections, the generating a rendered 3D visual model of the home, building or structure, and the generating one or more building materials files, with revision tracking.

13. The tangible, non-transitory, computer-readable media of claim 9, wherein the instructions further cause the processor to perform:
receiving a architectural detail file into a processor-based pipeline;
exporting the architectural detail file as an IFC (International Foundation Class) file;
loading the IFC file into a component design application;
generating a component design file, from the loaded IFC file;
exporting the component design file as a further IFC file;
merging the further IFC file with the earlier received architectural detail file, to form a merged architectural detail file; and
reprocessing in the processor-based pipeline, with the merged Revit file.

14. The tangible, non-transitory, computer-readable media of claim 13, wherein:
the architectural detail file or the merged architectural detail file is used for the 3D visual model; and
the component design file is used for generating the one or more building materials files.

15. A processor-based shoppable visual pipeline, comprising:
a processor;
a memory;
a 3D modeling engine;
a material calculating engine; and
the processor to:
receive user product selections for building materials that are represented in a 3D visual model for a structure;
generate, by the 3D modeling engine, a rendered 3D visual model of the structure based on the 3D visual model; and
generate, by the material calculating engine, one or more building materials files that list building materials or products corresponding to the user product selections and the representations thereof in the 3D visual model for the structure, for user purchase consideration.

16. The processor-based shoppable visual pipeline of claim 15, further comprising the processor to:
generate a user interface of the shoppable visual pipeline, arranged for the user product selections, user viewing of the rendered 3D visual model of the home, building or structure, and user viewing of contents of the one or more building materials files that list building materials or products for user purchase consideration.

17. The processor-based shoppable visual pipeline of claim 15, wherein:
the one or more building materials files include descriptions of the building materials or products, quantities thereof, SKU (stock keeping unit) or other ID thereof, and prices thereof; and
the one or more building materials files include description of at least one of the building materials or products and cutting dimensions thereof.

18. The processor-based shoppable visual pipeline of claim 15, further comprising the processor to:
iterate actions of receive user product selections, generate a rendered 3D visual model of the home, building or structure, and generate one or more building materials files, with revision tracking.

19. The processor-based shoppable visual pipeline of claim 15, further comprising the processor to:
receive an architectural detail file into a processor-based pipeline;
export the architectural detail file as an IFC (International Foundation Class) file;
load the IFC file into a component design application;
generate a component design file, from the loaded IFC file;
export the component design file as a further IFC file;
merge the further IFC file with the earlier received architectural detail file, to form a merged architectural detail file; and
reprocess in the processor-based pipeline, with the merged architectural detail file.

20. The processor-based shoppable visual pipeline of claim 19, wherein:
the architectural detail file or the merged architectural detail file is used for the 3D visual model; and
the component design file is used for generating the one or more building materials files.
